(19) United States
(12) Patent Application Publication
(10) Pub. No.: US 2026/0255557 A1
(43) Pub. Date: Aug. 27, 2026

(54) THERMAL MANAGEMENT SYSTEM AND HEAT DISSIPATION ASSEMBLY

(71) Applicant: SUPER MICRO COMPUTER, INC., San Jose, CA (US)

(72) Inventors: JOHN CHIANG, New Taipei City (TW); Chia-Wei Chen, New Taipei City (TW); Paxton Cheng, Taoyuan City (TW)

(21) Appl. No.: 19/064,600

(22) Filed: Feb. 26, 2025

(51) Int. Cl. H05K 7/20

(52) U.S. Cl. CPC H05K 7/20936; H05K 7/20327

(57) ABSTRACT

The present disclosure provides a thermal management system. The thermal management system includes a vapor chamber and a lid. The vapor chamber includes a first surface attachable to an electronic device and a second surface opposite to the first surface, wherein the vapor chamber contains a first working fluid within the vapor chamber. The lid is disposed on the second surface of the vapor chamber. The lid and the vapor chamber define a cavity for a second working fluid flowing through the cavity.

### TECHNICAL FIELD

The present disclosure relates to a thermal management system and a heat dissipation assembly. Specifically, the present disclosure relates to thermal management system including a vapor chamber with liquid cooling.

### BACKGROUND

Currently, the power consumption of chips (such as CPU and GPU) is getting higher, and the temperature of the chips and surrounding power regulating component, such as voltage regulator module (VRM), would also increase. Therefore, an improved thermal management system is called for.

### SUMMARY

In some embodiments, a thermal management system includes a vapor chamber and a lid. The vapor chamber includes a first surface attachable to an electronic device and a second surface opposite to the first surface, wherein the vapor chamber contains a first working fluid within the vapor chamber. The lid is disposed on the second surface of the vapor chamber. The lid and the vapor chamber define a cavity for a second working fluid flowing through the cavity.

In some embodiments, a heat dissipation assembly includes a vapor chamber, which includes a first surface attachable to an electronic device and a second surface opposite to the first surface. The vapor chamber includes an array of elliptical columns protruding from the second surface of the vapor chamber, and each of the elliptical columns is a hollow pipe with a closed end.

In some embodiments, a thermal management system includes a vapor chamber, a lid, and an inlet fitting and an outlet fitting located diagonally on the lid. The vapor chamber includes a first surface attachable to an electronic device and a second surface opposite to the first surface. The vapor chamber includes columns protruding from the second surface of the vapor chamber. The lid is disposed on the second surface of the vapor chamber to form a liquid cooling cavity between the lid and the vapor chamber, wherein the columns are accommodated within the liquid cooling cavity. The inlet fitting and outlet fitting are located diagonally on the lid for a liquid flow to pass through the liquid cooling cavity.

To improve heat dissipation, the subject disclosure provides a vapor chamber combined with the liquid cooling technology. In particular, the proposed vapor chamber can be a three-dimensional (3D) vapor chamber, which may contain a saturated working fluid and include multiple hollow columns protruding from the vapor chamber to enhance heat exchange. The hollow columns can be covered by a liquid cooling module. That is, the hollow columns can be positioned within a liquid cooling cavity, such that the heat brought by the hollow columns can be dissipated through the liquid flow within the liquid cooling cavity. The hollow columns provide more outer surface area for contacting the liquid, enhancing heat dissipation efficiency. Compared to the current 3D vapor chamber that utilizes an air-cooling concept, the proposed 3D vapor chamber employing liquid-cooling technology offers a more efficient heat exchange mechanism.

The hollow columns can be arranged in an array. Moreover, the hollow columns can have variable density depending on the location of heat sources. Columns located directly above heat sources exhibit a higher density, such that the heat can be dissipated faster. In some cases, hollow columns within a single 3D vapor chamber can have varying heights, depending on the location of heat sources. Taller columns can offer a greater outer surface area, thereby improving heat dissipation efficiency. Furthermore, the inlet and outlet of the liquid cooling cavity can be diagonally arranged. In such a case, the liquid can pass through the whole cavity, thereby enhancing the thermal convection.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features may be arbitrarily increased or reduced for clarity of discussion.

FIG. 1A is a three-dimensional view of a thermal management system, in accordance with some embodiments of the present disclosure.

FIG. 1B is an exploded view of a thermal management system, in accordance with some embodiments of the present disclosure.

FIG. 1C is a top view of a thermal management system, in accordance with some embodiments of the present disclosure.

FIG. 1D is a cross-section of a thermal management system along line A-A of FIG. 1C, in accordance with some embodiments of the present disclosure.

FIG. 2A is a top view of a vapor chamber, in accordance with some embodiments of the present disclosure.

FIG. 2B is a top view of a vapor chamber, in accordance with some embodiments of the present disclosure.

FIG. 3A is an exploded view of a thermal management system, in accordance with some embodiments of the present disclosure.

FIG. 3B is a cross-section of a thermal management system, in accordance with some embodiments of the present disclosure.

FIG. 4 is a cross-section of a thermal management system, in accordance with some comparative embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides different embodiments, or examples, for implementing different features of the provided subject matter. Specific examples of components and embodiments are recited herein. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. The present disclosure may repeat reference numerals and/or letters in the various examples. This repetition is for simplicity and clarity and does not in itself dictate a relationship between the various embodiments and/or configurations discussed.

Embodiments of the present disclosure are discussed in detail as follows. It should be appreciated, however, that the present disclosure provides many applicable concepts that can be embodied in a wide variety of specific contexts. The specific embodiments discussed are merely illustrative and do not limit the scope of the disclosure.

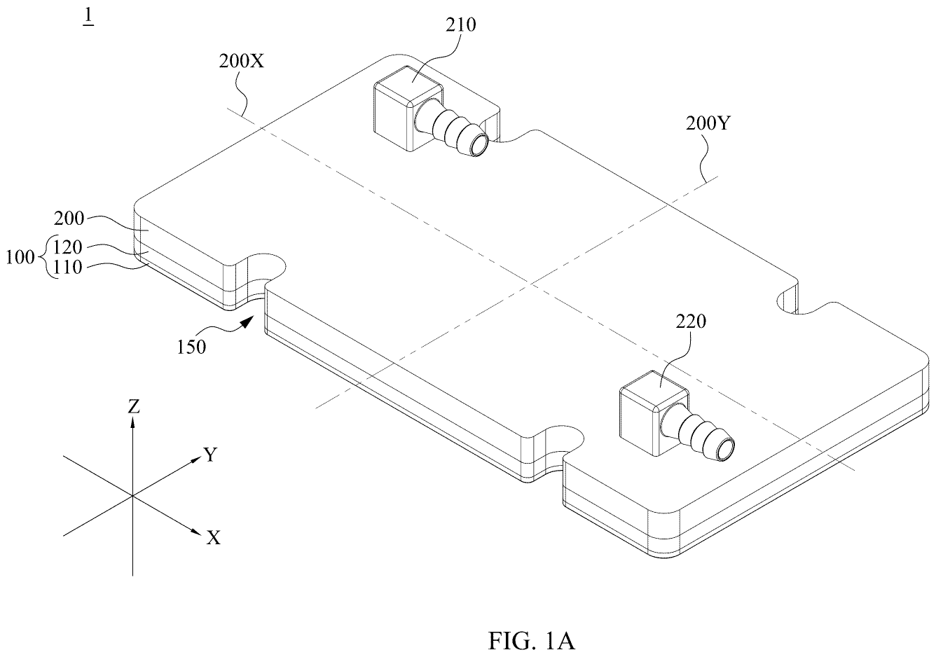

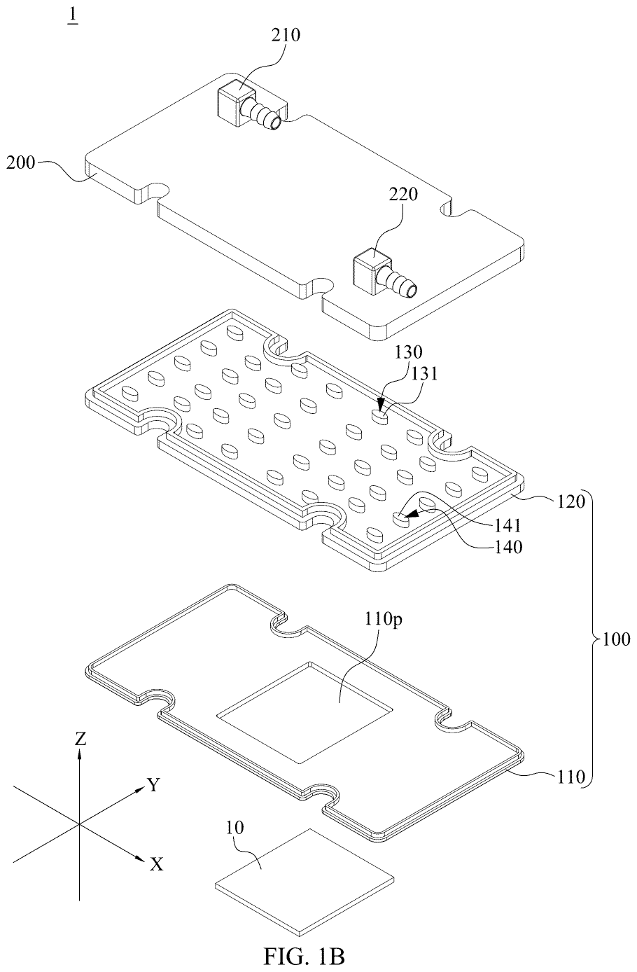

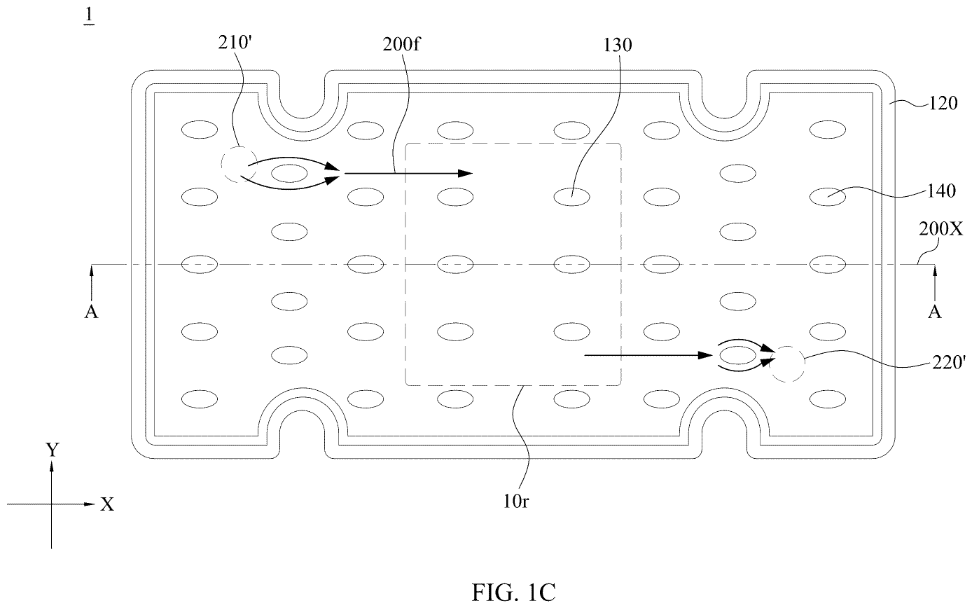

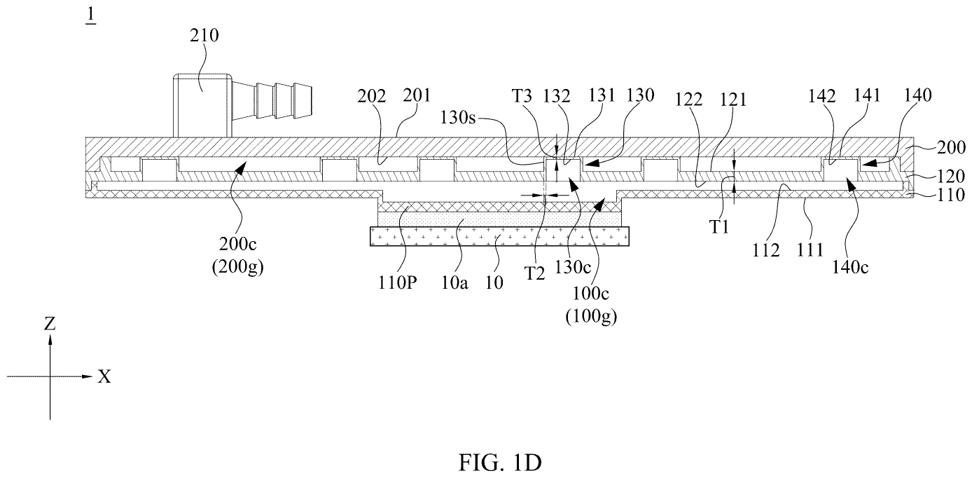

FIG. 1A is a three-dimensional view of a thermal management system 1, in accordance with some embodiments of the present disclosure. FIG. 1B is an exploded view of a thermal management system 1, in accordance with some embodiments of the present disclosure. FIG. 1C is a top view of a thermal management system 1, in accordance with some embodiments of the present disclosure. In FIG. 1C, the lid 200 is omitted for clarity. FIG. 1D is a cross-section of a thermal management system 1 along line A-A of FIG. 1C, in accordance with some embodiments of the present disclosure.

Referring to FIGS. 1A and 1B, the thermal management system 1 includes a vapor chamber 100 and a lid 200. The vapor chamber 100 includes a top plate 120 and a base plate 110, and the lid 200 includes an inlet fitting 210 and an outlet fitting 220 positioned on it. In some embodiments, the thermal management system 1 may be referred as a heat dissipation assemble, a cold plate, or the like. In some embodiments, the thermal management system 1 may be a three-dimensional vapor chamber incorporating liquid cooling mechanism.

The thermal management system 1 can be attached to an electronic device 10. Referring to FIG. 1B, the thermal management system 1 can be disposed on and in contact with the electronic device 10. In some embodiments, the thermal management system 1 can be configured to dissipate the heat generated by the electronic device 10. In some embodiments, the thermal management system 1 may be attached to one or more electronic devices 10. The electronic device 10 may include a power regulating component, such as voltage regulator module (VRM). In some embodiments, the thermal management system 1 and the electronic device 10 may be disposed on a substrate or a motherboard (not shown), which serves as the foundational platform for integrating various electronic components. The thermal management system 1 may be mounted on the substrate or the motherboard through corresponding recesses 150 using a connector or fastener (not shown), which ensures a secure and stable attachment, allowing for efficient heat dissipation.

In some embodiments, the vapor chamber 100 may be disposed on and contact the electronic device 10. The lid 200 can be disposed on the vapor chamber 100, and the inlet fitting 210 and the outlet fitting 220 can be arranged on the lid 200 for directing a working fluid to input from the inlet fitting 210 and to output from the outlet fitting 220. In some embodiments, the positions of the inlet fitting 210 and the outlet fitting 220 can be exchanged. The vapor chamber 100 may include a cavity 100c (see FIG. 1D) and contain a first working fluid 100g within the cavity 100c of the vapor chamber 100. In some embodiments, the lid 200 and the vapor chamber 100 may define a cavity 200c (see FIG. 1D) for a second working fluid 200g containing within and flowing through the cavity 200c. That is, the cavity 200c is between the lid 200 and the vapor chamber 100. For example, the second working fluid 200g can be input to the cavity 200c through the inlet fitting 210 and be output from the cavity 200c through the outlet fitting 220. In some embodiments, the volume of the cavity 100c may be equal to or less than that of the cavity 200c. In some embodiments, the first working fluid 100c and the second working fluid 200 g may include pure water, PG25 (coolant properties of 25% propylene glycol), or other suitable coolants. In some embodiments, the first working fluid 100c may be the same as the second working fluid 200c. In another embodiment, the first working fluid 100c may be different from the second working fluid 200c. For example, the first working fluid 100c may be PG25, and the second working fluid 200c may be pure water.

In some embodiments, the inlet fitting 210 and the outlet fitting 220 can be arranged on opposite sides of the lid 200. For example, the inlet fitting 210 and the outlet fitting 220 is arranged on opposite sides of a symmetry axis 200X of the lid 200 (see FIG. 1A). Additionally, the inlet fitting 210 and the outlet fitting 220 can be arranged on opposite sides of a symmetry axis 200Y of the lid 200 (see FIG. 1A). The arrangement of the inlet fitting 210 and the outlet fitting 220 facilitate the second working fluid 200g to flow through the cavity 200c, from the inlet fitting 210 to the outlet fitting 220. The inlet fitting 210 and the outlet fitting 220 may be misaligned with the symmetry axis 200X or 200Y of the lid 200 (see FIG. 1A), where the symmetry axis 200X may be orthogonal to the symmetry axis 200Y. For example, the inlet fitting 210 and the outlet fitting 220 may be located diagonally on the lid 200 for facilitating a liquid flow passing through the cavity 200c.

In some embodiments, the inlet fitting 210 and the outlet fitting 220 may include a thermal conductive material such as a metal or metal alloy. Examples of the thermal conductive material include copper (Cu), aluminum (Al), or an alloy thereof. In some embodiments, the inlet fitting 210 and the outlet fitting 220 may be bonded to the lid 200 by welding or other suitable manners.

In some embodiments, the vapor chamber 100 can include a top plate 120 and a base plate 110. The top plate 120 may be disposed on and connected to the base plate 110. In some embodiments, the top plate 120 and the base plate 110 may include a thermal conductive material such as a metal or metal alloy. Examples of the thermal conductive material include copper (Cu), aluminum (Al), or an alloy thereof. In some embodiments, the top plate 120 may be bonded or sealed to the base plate 110 through welding or other suitable methods. In some embodiments, the top plate 120 and the base plate 110 may have corresponding fitting structures at their edges to fit together more securely, and then be bonded by welding.

Referring to FIG. 1B, the base plate 110 of the vapor chamber 100 has a portion 110P protruding away from the lid 200. The portion 110P of the base plate 110 may be arranged to contact the electronic device 10. Referring to FIG. 1D, the portion 110P may be connected to the electronic device 10 through a thermal adhesive 10a. In some embodiments, the base plate 110 has a bottom surface 111 and a top surface 112 opposite to the bottom surface 111. The bottom surface 111 and the top surface 112 may be the outer surface and the inner surface of the vapor chamber 100, respectively. The bottom surface 111 may be attachable to the electronic device 10. In other words, the electronic device 10 may be attached to the bottom surface 111 of the vapor chamber 100 through the thermal adhesive 10a. For example, the thermal adhesive 10a may be the thermal interface materials (TIM). The thermal interface material (TIM) is designed to conduct heat from the electronic device 10 to the heat spreader, such as, the vapor chamber 100. In some embodiments, the shape of the portion 110P may be substantially aligned to that of the electronic device in the top view. For example, the width of the portion 110P may be substantially identical to that of the electronic device 10. In another embodiment, the base plate 110 may have more than one portions 110P to correspond to more than one electronic devices 10. In other embodiments, the base plate 110 may not include any portion 110P, resulting in a flat bottom surface 111.

Referring to FIG. 1B, the top plate 120 of the vapor chamber 100 may include one or more columns 130 and columns 140 arranged in an array. In some embodiments, the columns 130 and 140 may be covered by the lid 200 and within the cavity 200c. The columns 130 and 140 can protrude toward the lid 200. The columns 130 and 140 may be accommodated within the cavity 200c, i.e., the liquid cooling cavity. In some embodiments, the columns 130 and 140 may be evenly distributed to facilitate uniform heat dissipation.

Referring to FIG. 1C, the columns 130 may be located above the electronic device 10 and in a middle portion of the top plate 120 of the vapor chamber 100. The columns 140 may be located at periphery of the top plate 120. In some embodiments, the electronic device 10 is located under the middle portion of the top plate 120. The columns 130 are close to the electronic device 10 than the columns 140 are. In some embodiments, the columns 130 may include a first group located within a region 10r above the electronic device 10 and a second group outside the region 10r. In some embodiments, the columns 130 are located between the columns 140. The columns 140 may include two groups arranged in opposite sides of the columns 130 and outside the region 10r.

FIG. 1C shows corresponding locations of inlet fitting 210 and outlet fitting 220, labeled as 210′ and 220′, respectively. The inlet fitting 210 and the outlet fitting 220 non-overlap the columns 130 and/or 140. In some embodiments, the second working fluid 200g can be input to the cavity 200c (between the lid 200 and the top plate 120) through the inlet fitting 210. For example, the second working fluid 200g can pass through the cavity 200c along a liquid flow 200f. The second working fluid 200g can pass through the cavity 200c and output through the outlet fitting 220. The diagonal arrangement of the inlet fitting 210 and outlet fitting 220 allows the second working fluid 200g to fully pass through the entire cavity 200c, carrying away the heat from the columns 130 and 140, thereby enhancing the thermal dissipation.

In some embodiments, the columns 130 and 140 may be cylindrical, elliptical, rectangular, or other profiles. The columns 130 and 140 can have a geometric shape extending in a direction substantially aligned with the liquid flow 200f of the second working fluid 200g (in the cavity 200c). In some embodiments, when the columns 130 and 140 are elliptical columns with flat ends, each of the columns 130 and 140 may include an elliptical upper surface 131 and 141 (see FIG. 1B). Referring to FIG. 1C, a major axis of the upper surface 131 and 141 of the elliptical columns 130 and 140 is oriented along the symmetry axis 200X of the lid 200. In another embodiment, the columns 130 and 140 can have a rounded or circular end (not shown).

Referring to FIG. 1D, the top plate 120 has a top surface 121 and a bottom surface 122 opposite to the top surface 121. The top surface 121 and the bottom surface 122 may be the outer surface and the inner surface of the vapor chamber 100, respectively. In some embodiments, the lid 200 may be disposed on the top surface 121 of the top plate 120 of the vapor chamber 100 to create the cavity 200c. In some embodiments, the columns 130 and 140 can protrude from the top surface 121 toward the lid 200. The height of the columns 130 may be substantially identical to that of the columns 140.

Each of the columns 130 can include a hollow pipe (or tube) 130c with a closed (flat or rounded) end contacting the lid 200. In some embodiments, the columns 130 may have a sidewall 130s, which has a thickness T2 less than a thickness T1 of the top plate 120. The thickness T1 may be defined by the top surface 121 and the bottom surface 122. That is, the columns 130 have a thin sidewall (i.e., the sidewall 130s) to enhance thermal conductivity. The columns 130 may have an outer surface (for example, the upper surface 131) and an inner surface 132. The upper surface 131 may contact the lid 200. When the columns 130 have a flat end, a thickness T3 defined by the outer surface 131 and the inner surface 132 may be less than the thickness T1. The thickness T2 of the sidewall 130s may be substantially identical to the thickness T3.

The outer surface 131 of the columns 130 may contact an inner surface 202 of the lid 200, which is opposite to an outer surface 201 of the lid 200. In some embodiments, a thickness of the lid 200, defined by the outer surface 201 and the inner surface 202, may be greater than or identical to the thickness T1 of the top plate 120 of the vapor chamber 100. In some embodiments, a thickness of the base plate 110, defined by the bottom surface 111 and the top surface 112, may be less than or substantially equal to the thickness T1 of the top plate 120 of the vapor chamber 100.

The characteristics of columns 140 are similar to those of columns 130. Each of the columns 140 can include a hollow pipe (or tube) 140c with a closed (flat or rounded) end contacting the lid 200. The columns 140 may have an outer surface (for example, the upper surface 141) and an inner surface 142. The upper surface 141 may contact the lid 200. Likewise, the columns 140 may include a sidewall and/or a flat end thinner than the thickness T1 of the top plate 120.

The columns 130 and 140 are filled with the saturated first working fluid 100g and surrounded by the second working fluid 200g in the cavity 200c. To dissipate heat, the vaporized first working fluid 100g can fill in the columns 130 and 140, such that the second working fluid 200g can dissipate the heat brought by the vaporized first working fluid 100g through the columns 130 and 140.

The cavity 100c of the vapor chamber 100 is in fluid communication with the hollow pipes 130c of the columns 130 and the hollow pipes 140c of the columns 140 and is partially filled with saturated first working fluid 100g. Saturated first working fluid 100g exists in a liquid state at the bottom of each of the columns 130 and 140, i.e., at the cavity 100c. When/while receiving thermal energy from heat sources (such as the electronic device 10) through the bottom surface 111 of the base plate 110 (or the portion 110P), some of the saturated first working fluid 100g in the cavity 100c may vaporize or evaporate as gas rising into hollow pipes 130c of the columns 130 and the hollow pipes 140c of the columns 140, and eventually condenses as liquid droplets that return (by gravitational force) to the cavity 100c. As the vapor cools, the vapor undergoes a phase change from gas back to liquid. Condensation occurs on the sidewalls and top surfaces of columns 130 and 140 when the heat from the rising vapor is absorbed and removed by the liquid flow 200f of the second working fluid 200g in the cavity 200c. The thermal energy received at the base of the cavity 100c of the vapor chamber 100 from the electronic device 10 is conveyed upward through the columns 130 and 140 via evaporation of the saturated first working fluid 100g. Subsequently, the thermal energy is absorbed by the cooling liquid (i.e., the second working fluid 200g) through condensation of the vaporized form of the saturated first working fluid 100g.

The thermal management system 1 may be configured as a 3D vapor chamber containing a saturated working fluid 100g in the cavity 100c that undergoes phase changes to facilitate the heat transfer from the heat sources (i.e., the electronic device 10) and the heat dissipation via conduction and convection from the columns 130 and 140 to the cooling liquid (i.e., the second working fluid 200g in the cavity 200c). Moreover, the hollow columns (for example, columns 130 and 140) can be covered by the liquid cooling module (for example, the lid 200). The columns 130 and 140 can be located within the cavity 200c, such that the heat brought by the vaporized first working fluid 100g in the columns 130 and 140 can be dissipated through the liquid flow 200f of the second working fluid 200g. The columns 130 and 140 can provide more outer surface area for contacting the second working fluid 200g in the cavity 200c, enhancing heat dissipation efficiency.

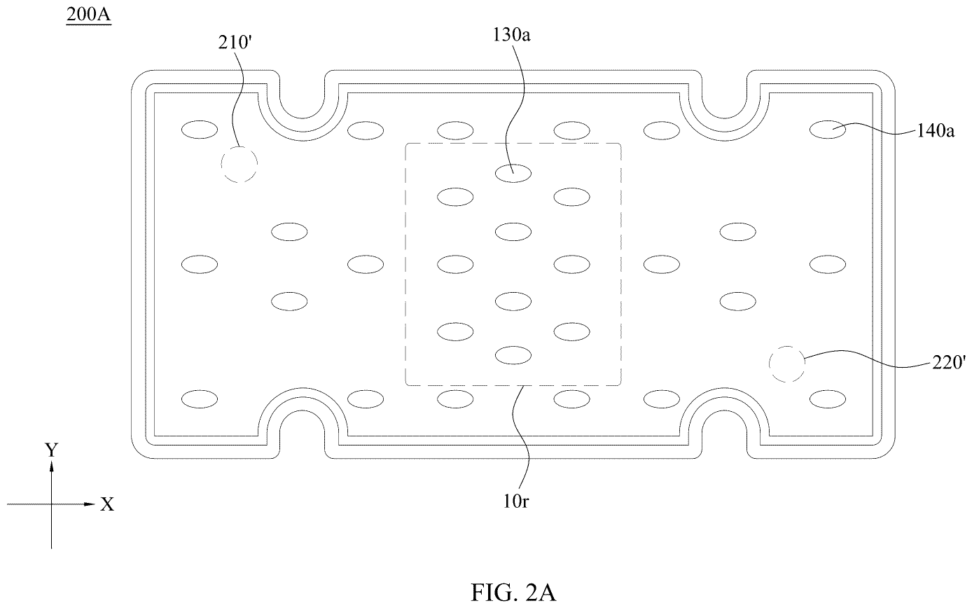

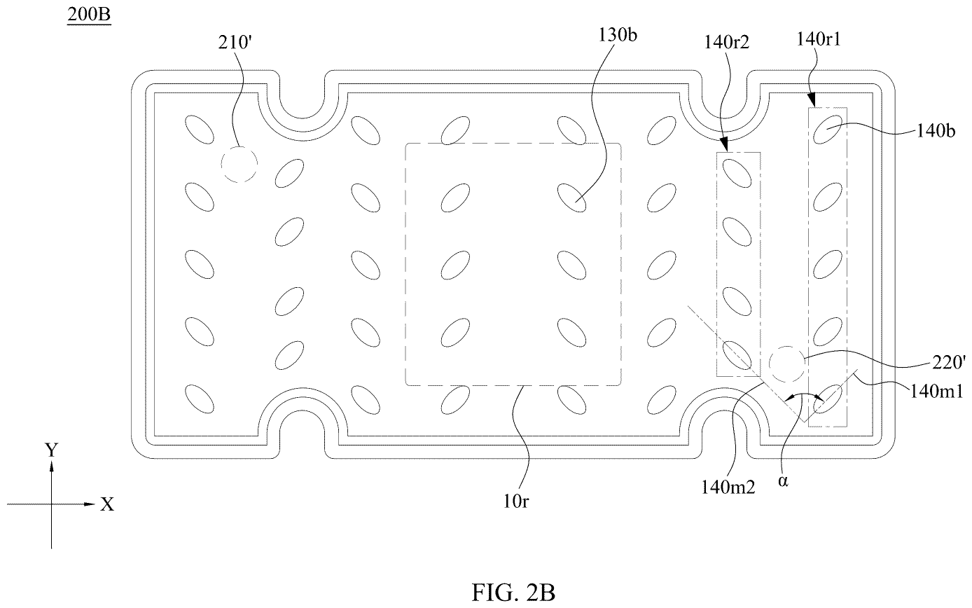

FIG. 2A is a top view of a vapor chamber 200A, in accordance with some embodiments of the present disclosure. The vapor chamber 200A of FIG. 2A is similar to the vapor chamber 100 depicted in FIG. 1A to FIG. 1D, but features a different arrangement of columns 130a and 140a. Referring to FIG. 2A, the columns 130a may include a first group of columns located within the region 10r above the electronic device 10 and a second group of columns located outside the region 10r. The columns 140s may be located outside the region 10r and at periphery of the vapor chamber 200A. In some embodiments, a density of the columns 130a located in the region 10r may be greater than that of the columns 130a outside the region 10r. The density of the columns 130a located in the region 10r may be greater than that of the columns 140a. That is, a distance between adjacent columns 130a is less than a distance between adjacent columns 140a. The columns 130a in the region 10r are arranged more closely to better dissipate the heat generated by the electronic device 10 below the region 10r.

The columns 130a and 140a can have a variable density, depending on the location of heat sources. Columns 130a situated directly above heat sources exhibit higher density, such that the heat can be dissipated faster.

FIG. 2B is a top view of a vapor chamber 200B, in accordance with some embodiments of the present disclosure. The vapor chamber 200B of FIG. 2B is similar to the vapor chamber 100 depicted in FIG. 1A to FIG. 1D, but features a different arrangement (such as the orientation) of columns 130b and 140b. Referring to FIG. 2B, the columns 130b and 140b in adjacent vertical rows extend in different directions. For example, in X-direction, adjacent columns (130b or 140b) are oriented substantially perpendicular to each other. In contrast, in Y-direction, adjacent columns (130b or 140b) are oriented substantially parallel to each other.

In some embodiments, the columns 140b may include a first row 140r1 and a second row 140r2 adjacent to the first row 140r1. The first row 140r1 and the second row 140r2 are vertical rows. In some embodiments, the first row 140r1 can include five columns 140b, and the second row 140 r2 can include four columns 140b. In some embodiments, major axes 140m1 of the columns 140b in the first row 140r1 are substantially parallel. Major axes 140m2 of the columns 140b in the second row 140r2 are substantially parallel. The major axis 140m1 of one of the columns 140b in the first row 140r1 and the major axis 140m2 of one of the columns 140b in the second row 140r2 form an angle α. The angle α may be about or less than 90°. For example, the major axes 140m2 of the columns 140b in the second row 140r2 are substantially perpendicular to the major axes 140m1 of the columns 140b in the first row 140r1.

The columns 130b and 140b, oriented in different directions, facilitate increased contact between the liquid flow in the cavity 200c and the outer surfaces of columns 130b and 140b, thereby enhancing the heat exchange. Accordingly, the second working fluid 200g, input from the inlet fitting 210, passes through the cavity 200c in a zigzag liquid flow and then output at the outlet fitting 220. In such a case, the second working fluid 200g can pass through the entire cavity 200c, thereby enhancing the thermal efficiency.

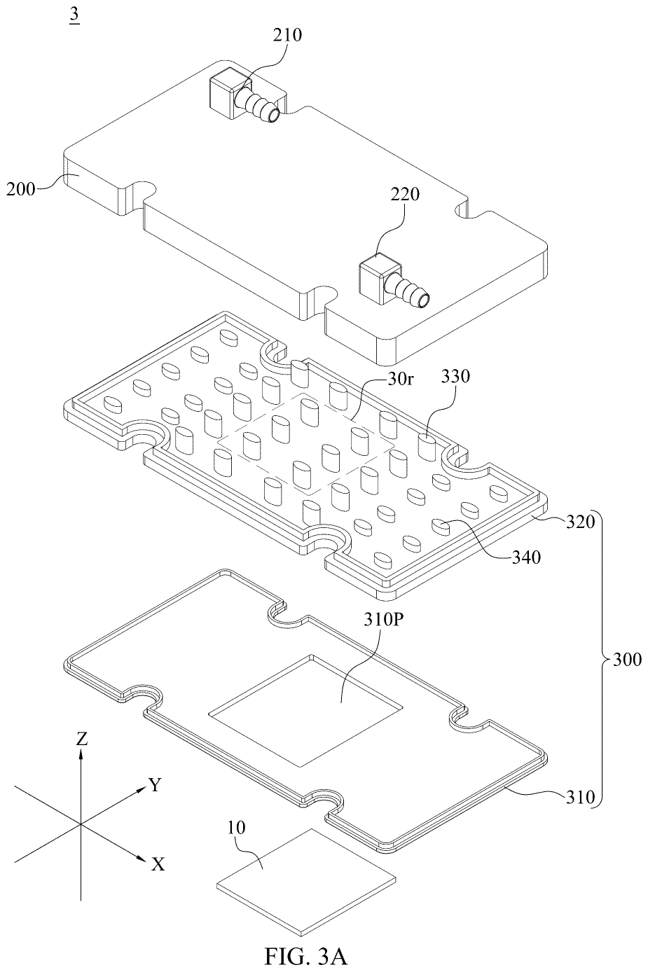

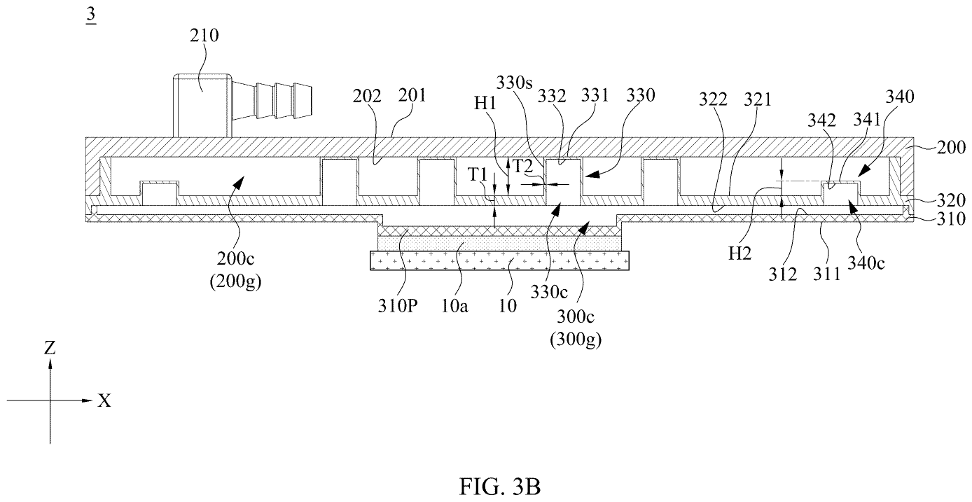

FIG. 3A is an exploded view of a thermal management system 3, in accordance with some embodiments of the present disclosure. FIG. 3B is a cross-section of a thermal management system 3, in accordance with some embodiments of the present disclosure. The thermal management system 3 of FIGS. 3A and 3B is similar to the thermal management system 1 of FIG. 1A to FIG. 1D, but features a different arrangement of columns, particularly with different column heights.

Referring to FIGS. 3A and 3B, the thermal management system 3 includes a vapor chamber 300, a lid 200, an inlet fitting 210, and an outlet fitting 220. The vapor chamber 300 can include a top plate 320 and a base plate 310. The base plate 310 is the same as the base plate 110 of the vapor chamber 100 in FIG. 1A to FIG. 1D.

In some embodiments, the top plate 320 of the vapor chamber 300 may include one or more columns 330 and columns 340 arranged in an array. In some embodiments, the columns 330 and 340 may be covered by the lid 200 and within the cavity 200c. The columns 330 and 340 can protrude toward the lid 200. The columns 330 and 340 may be accommodated within the cavity 200c, i.e., the liquid cooling cavity. In some embodiments, the columns 330 and 340 may be evenly distributed to facilitate uniform heat dissipation.

The columns 330 may be located above the electronic device 10 and in a middle portion of the top plate 320 of the vapor chamber 300. The columns 340 may be located at periphery of the top plate 320. In some embodiments, the electronic device 30 is located under the middle portion of the top plate 320. The columns 330 are close to the electronic device 10 than the columns 340 are. In some embodiments, the columns 330 may include a first group located within a region 30r above the electronic device 30, and a second group outside the region 30r. The columns 330 is located between the columns 340. The columns 340 may include two groups arranged adjacent to the columns 330 and in opposite sides of the columns 330, located outside the region 30r.

Referring to FIG. 3B, a height H1 of the columns 330 may be different from a height H2 of the columns 340. For example, the height H1 of the columns 330 may be greater than the height H2 of the column 340. In some embodiments, a top surface 331 of the columns 330 may contact the inner surface 202 of the lid 200, and a top surface 341 of the columns 340 may not contact the inner surface 202 of the lid 200. That is, an elevation of the top surface 331 may be different from that of the top surface 341. For example, the elevation of the top surface 331 may be higher than that of the top surface 341. In such a case, the second working fluid 200g may flow over and contact the top surface 341 of the columns 340. In some embodiments, the volume of the cavity 200c can be equal to or greater than the volume of the cavity 100c.

The columns 330 and 340 can have variable heights, depending on the location of heat sources. The higher columns 330 can provide more outer surface area to enhance heat dissipation efficiency. In some embodiments, the higher columns 330 can be arranged above the heat sources (such as the electronic device 30).

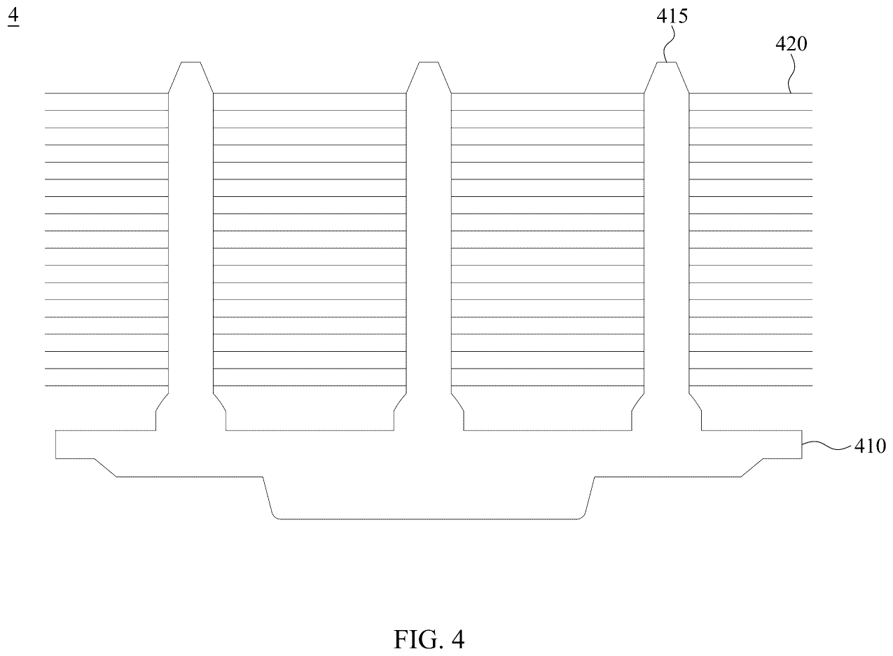

FIG. 4 is a cross-section of a thermal management system 4, in accordance with some comparative embodiments of the present disclosure. The thermal management system 4 includes a vapor chamber 410 with multiple hollow columns 415 protruding from the vapor chamber 410 and one or more fins 420 connected to the hollow columns 415. In some embodiments, the thermal management system 4 may be disposed on heat sources (not shown), such as electronic devices. The heat sources may be located under and contact the vapor chamber 410.

The vapor chamber 410 may contain a saturated working fluid. When/while receiving thermal energy from heat sources through the bottom surface of the vapor chamber 410, some of the saturated working fluid may vaporize or evaporate as gas rising to the hollow columns 415, and eventually condenses as liquid droplets that return (by gravitational force) to the bottom of the vapor chamber 410. Condensation occurs on the sidewalls and top surfaces of hollow columns 415 when the heat from the rising vapor is absorbed by the fins 420 and is removed by air-cooling. As the vapor cools, the vapor undergoes a phase change from gas back to liquid. The thermal energy received at the base of the vapor chamber 410 from the heat sources is conveyed upward through the hollow columns 415 via evaporation of the saturated working fluid. Subsequently, the thermal energy is absorbed by the fins 420 through condensation of the vaporized form of the saturated working fluid. The thermal energy absorbed by the fins 420 can be dissipated, for example, through a fan (not shown) attached above the thermal management system 4. The hollow columns 415 of the vapor chamber 410 can have a sufficient height to connect to enough fins 420. The minimum height of hollow columns 415 has certain requirements; otherwise, the heat dissipation efficiency of thermal management system 4 may not meet expectations. Accordingly, the subject disclosure proposes a thermal management providing a vapor chamber combined with the liquid cooling technology. As the thermal efficiency of the liquid-cooling is better than air-cooling, the proposed thermal management system 1 or 3 can have a smaller size (height/thickness) compared to the thermal management system 4.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A thermal management system, comprising:
a vapor chamber including a first surface attachable to an electronic device and a second surface opposite to the first surface, wherein the vapor chamber contains a first working fluid within the vapor chamber; and
a lid disposed on the second surface of the vapor chamber, wherein the lid and the vapor chamber define a cavity for a second working fluid flowing through the cavity.

2. The system of claim 1, further comprising an inlet fitting and an outlet fitting arranged on opposite sides of the lid for the second working fluid to flow from the inlet fitting to the outlet fitting through the cavity, wherein the inlet fitting and the outlet fitting are misaligned with an axis of symmetry of the lid.

3. The system of claim 1, wherein the vapor chamber includes columns protruding from the second surface toward the lid.

4. The system of claim 3, wherein each of the columns includes an elliptical upper surface.

5. The system of claim 4, wherein a major axis of the elliptical upper surface of the columns is oriented along an axis of symmetry of the lid.

6. The system of claim 3, wherein the columns include a first group of columns located within a first region above the electronic device and a second group of columns located outside the first region, wherein a column density of the first group of columns is greater than that of the second group of columns.

7. The system of claim 3, wherein each of the columns comprises a hollow pipe with a closed end contacting the lid, wherein the columns are filled with the first working fluid and surrounded by the second working fluid.

8. The system of claim 1, wherein the vapor chamber has a portion protruding away from the lid, wherein the portion is arranged to contact the electronic device.

9. The system of claim 3, wherein the columns include a first group of columns located within a first region and a second group of columns located outside the first region, wherein a height of the first group of columns is different from that of the second group of columns.

10. A heat dissipation assembly, comprising:
a vapor chamber including a first surface attachable to an electronic device and a second surface opposite to the first surface, wherein the vapor chamber includes an array of elliptical columns protruding from the second surface of the vapor chamber, wherein each of the elliptical columns is a hollow pipe with a closed end.

11. The heat dissipation assembly of claim 10, wherein the vapor chamber includes a top plate and a base plate, wherein a thickness of a sidewall of the elliptical columns is less than a thickness of the top plate.

12. The heat dissipation assembly of claim 10, further comprising a lid covering the elliptical columns to form a cavity between the lid and the vapor chamber for a working fluid flowing through the cavity, wherein a top surface of a first one of the elliptical columns contacts an inner surface of the lid, and a top surface of a second one of the elliptical columns free of contacting the inner surface of the lid.

13. The heat dissipation assembly of claim 10, wherein the elliptical columns include a first group of elliptical columns located above the electronic device and a second group of elliptical columns adjacent to the first group, wherein a height of the first group of elliptical columns is greater than that of the second group of elliptical columns.

14. The heat dissipation assembly of claim 10, wherein major axes of the elliptical columns in a first row of the array are substantially parallel.

15. The heat dissipation assembly of claim 14, wherein major axes of the elliptical columns in a second row of the array is substantially perpendicular to that of the elliptical columns in the first row.

16. A thermal management system, comprising:
a vapor chamber including a first surface attachable to an electronic device and a second surface opposite to the first surface, wherein the vapor chamber includes columns protruding from the second surface of the vapor chamber;
a lid disposed on the second surface of the vapor chamber to form a liquid cooling cavity between the lid and the vapor chamber, wherein the columns are accommodated within the liquid cooling cavity; and
an inlet fitting and an outlet fitting located diagonally on the lid for a liquid flow to pass through the liquid cooling cavity.

17. The system of claim 16, wherein the columns have a geometric shape extending in a direction aligned with the liquid flow in a top view.

18. The system of claim 16, wherein the inlet fitting and the outlet fitting non-overlap the columns.

19. The system of claim 16, wherein the electronic device is attached to the first surface of the vapor chamber through a thermal adhesive.

20. The system of claim 16, wherein the electronic device comprises a power regulating component.
